(19) United States
(12) Patent Application Publication
(10) Pub. No.: US 2006/0054986 A1
(43) Pub. Date: Mar. 16, 2006

(54) Image sensor with multilevel binary optics element

(75) Inventor: Tai-Cherng Yu, Tu-cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/117,232

(22) Filed: Apr. 28, 2005

(30) Foreign Application Priority Data
Sep. 11, 2004 (CN) 200420088210.2

(51) Int. Cl. H01L 31/0232

(52) U.S. Cl. 257/432

(57) ABSTRACT

An image sensor includes a substrate (41), an interlayer (42) on the substrate and a lens layer (40) on the interlayer. The substrate is a silicon layer. A plurality of photodiodes (411) are arranged in a matrix in an upper surface portion of the substrate. The interlayer includes an opaque metal layer (421) and a transparent color filter layer (422). The metal layer overlies portions of the upper surface of the substrate between the photodiodes. The color filter layer covers the metal layer and the photodiodes. The lens layer includes a plurality of multilevel binary optics elements (43). Each of the multilevel binary optics elements is located above a corresponding one of the photodiodes. By using the multilevel binary optics elements instead of conventional spherical microlenses, the optical capability of the image sensor is improved.

### BACKGROUND OF THE INVENTION

1. Field of the Invention

The present invention relates to an image sensor used in products such as digital cameras, and particularly to an image sensor having enhanced optical capability.

2. Description of the Related Art

Recently, remarkable improvements in CPU (central processing unit) performance and rapid progress in image processing technology and the like have enabled easy processing of digital image data. Digital cameras which can readily pick up good quality images have become increasingly prevalent. In particular, cellular phones and PDAs (personal digital assistants) equipped with a digital camera have appeared on the market in large numbers. Further, significant improvements in data transfer rates in radio communication have been realized. The transfer of image data between these types of cellular phones and PDAs is frequently carried out. An image sensor which can convert light signals into electrical signals is an important component of an image pickup device of a digital camera. Image sensors have received much attention lately.

FIG. 2 shows a conventional Complementary Metal-Oxide Semiconductor (CMOS) image sensor 100. The CMOS image sensor 100 includes a substrate 10, an interlayer 20 on the substrate 10, and a lens layer 30 on the interlayer 20. The substrate 10 is a semiconductor layer. A plurality of photodiodes 12 are provided in an upper surface portion of the substrate 10. The photodiodes 12 are arranged in a matrix. The interlayer 20 includes an opaque metal layer 21 and a transparent color filter layer 22. The metal layer 21 overlies portions of the upper surface of the substrate 10 between the photodiodes 12. The color filter layer 22 covers the metal layer 21 and the photodiodes 12. The lens layer 30 includes a plurality of microlenses 31 arranged in a matrix. Each of the microlenses 31 is located above a corresponding one of the photodiodes 12. However, the microlenses 31 are spherical lenses which are prone to high aberrations. Therefore the optical performance of the CMOS image sensor 100 may not be satisfactory.

What is needed, therefore, is an image sensor which overcomes the above-described disadvantage and has good optical capability.

### SUMMARY

An image sensor of a preferred embodiment of the present invention includes a substrate, an interlayer on the substrate and a lens layer on the interlayer. The substrate is a silicon layer. A plurality of photodiodes are arranged in a matrix in an upper surface portion of the substrate. The interlayer includes an opaque metal layer and a transparent color filter layer. The metal layer overlies portions of the upper surface of the substrate between the photodiodes. The color filter layer covers the metal layer and the photodiodes. The lens layer includes a plurality of multilevel binary optics elements. Each of the multilevel binary optics elements is located above a corresponding one of the photodiodes.

By using the multilevel binary optics elements instead of conventional spherical microlenses, the optical capability of the image sensor is improved.

Other objects, advantages and novel features of the invention will become more apparent from the following detailed description of a preferred embodiment thereof when taken in conjunction with the accompanying drawings, in which:

### BRIEF DESCRIPTION OF THE DRAWINGS

FIG. 1 is a schematic, cross-sectional view of a CMOS image sensor in accordance with a preferred embodiment of the present invention; and

FIG. 2 is a schematic, cross-sectional view of a conventional CMOS image sensor.

### DETAILED DESCRIPTION OF PREFERRED EMBODIMENT

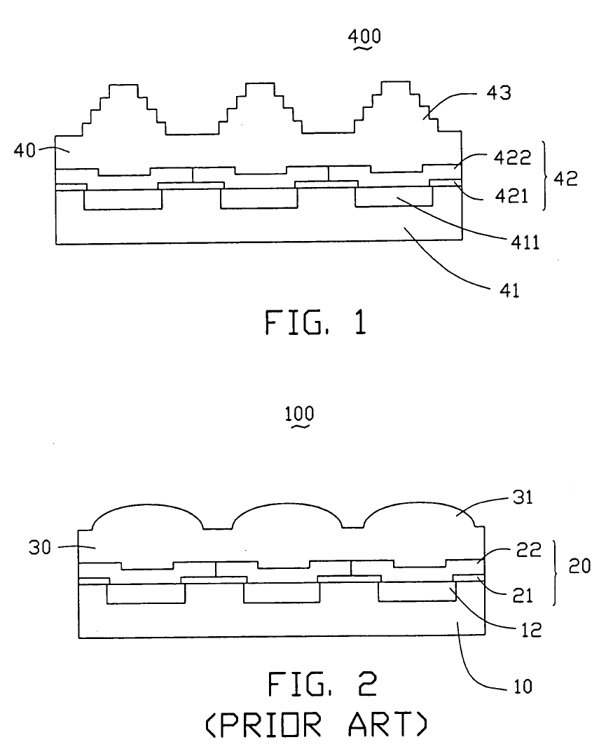

Referring to FIG. 1, a CMOS image sensor 400 installed in a frame of an image-taking device in accordance with a preferred embodiment of the present invention includes a substrate 41, an interlayer 42 on the substrate 41, and a lens layer 40 on the interlayer 42. The substrate 41 is a semiconductor layer. The semiconductor can be silicon or germanium. A plurality of photodiodes 411 as image-taking units are arranged in a matrix in an upper surface portion of the substrate 41 to generate electrical signals corresponding to the taken images. The interlayer 42 includes an opaque metal layer 421 and a transparent color filter layer 422. The metal layer 421 overlies portions of the upper surface of the substrate 41 between the photodiodes 411. The color filter layer 422 covers the metal layer 421 and the photodiodes 411. The lens layer 40 is a multilevel binary optics element array, which is capable of eliminating aberrations and means a plurality of mutilevel binary optics elements 43 arranged in matrix. Each of the mutilevel binary optics elements 43 is located above a corresponding one of the photodiodes 411. The multilevel binary optics element 43 can be a Fresnel lens.

Each multilevel binary optics element 43 has a characteristic of low aberration. Therefore, by using the multilevel binary optics elements 43, the optical capability of the CMOS image sensor 400 is improved.

It is believed that the preferred embodiment and its advantages will be understood from the foregoing description described merely being preferred or exemplary embodiments of the invention, and it will be apparent that various changes may be made thereto without departing from the spirit and scope of the invention.

I claim:

1. An image sensor comprising:
a substrate;
an interlayer on the substrate; and
a lens layer on the interlayer;
wherein the lens layer is a multilevel binary optics element array comprising a plurality of multilevel binary optics elements.

2. The image sensor as claimed in claim 1, wherein the multilevel binary optics element is Fresnel lens.

3. The image sensor as claimed in claim 1, wherein the substrate is a semiconductor layer, and a plurality of photodiodes are arranged at an upper surface of the substrate.

4. The image sensor as claimed in claim 3, wherein the interlayer comprises a metal layer overlying portions of the upper surface of the substrate not having the photodiodes, and a color filter layer covering the metal layer and the photodiodes.

5. The image sensor as claimed in claim 4, wherein each of the multilevel binary optics elements is located corresponding to a respective one of the photodiodes.

6. The image sensor as claimed in claim 3, wherein the semiconductor layer is a silicon layer.

7. The image sensor as claimed in claim 3, wherein the semiconductor layer is a germanium layer.

8. An image-taking device comprising:
a frame enclosing said image-taking device; and
an image sensor installed in said frame and used to take images of an object for said device, said image sensor comprising a plurality of image-taking units used to generate electrical signals corresponding to said taken images of said object, and at least one multilevel binary optics element formed between each of said plurality of image-taking units and said object.

9. The image-taking device as claimed in claim 8, wherein said plurality of image-taking units is a plurality of photodiodes, and said at least one multilevel binary optics element is arranged as an array so as to be disposed between each of said plurality of photodiodes and said object.

10. An image-taking device comprising:
a frame enclosing said image-taking device; and
an image sensor installed in said frame and used to take images of an object for said device, said image sensor comprising a plurality of image-taking units used to generate electrical signals corresponding to said taken images of said object, and an aberration eliminating layer formed between each of said plurality of image-taking units and said object so as to eliminate undesired aberrations of said taken images.

11. The image-taking device as claimed in claim 10, wherein said plurality of image-taking units is a plurality of photodiodes, and said aberration eliminating layer comprises an array of multilevel binary optics elements located respectively between each of said plurality of photodiodes and said object.
